(19) United States
(12) Patent Application Publication
(10) Pub. No.: US 2004/0004268 A1
(43) Pub. Date: Jan. 8, 2004

(54) E-Fuse and anti-E-Fuse device structures and methods

(75) Inventors: Jeffrey S. Brown, Middlesex, VT (US); Robert J. Gauthier JR., Hinesburg, VT (US); Jed H. Rankin, South Burlington, VT (US); William R. Tonti, Essex Junction, VT (US)

Correspondence Address: SCULLY SCOTT MURPHY & PRESSER, PC, 400 GARDEN CITY PLAZA, GARDEN CITY, NY, 11530

(73) Assignee: International Business Machines Corporation, Armonk, NY

(21) Appl. No.: 10/064,376

(22) Filed: Jul. 8, 2002

(51) Int. Cl. H01L 29/00

(52) U.S. Cl. 257/529

(57) ABSTRACT

Standard photolithography is used to pattern and fabricate a final polysilicon wafer imaged structure which is smaller than normal allowable photo-lithographic minimum dimensions. Three different methods are provided to produce such sub-minimum dimension structures, a first method uses a photolithographic mask with a sub-minimum space between minimum size pattern features of the mask, a second method uses a photolithographic mask with a sub-minimum widthwise jog or offset between minimum size pattern features of the mask, and a third method is a combination of the first and second methods. Each of the three methods can be used with three different embodiments, a first embodiment is a polysilicon E-Fuse with a sub-minimum width polysilicon fuse line, a second embodiment is a work function altered/programmed self-aligned MOSFET E-Fuse with a sub-minimum width fuse line, and a third embodiment is a polysilicon MOSFET E-Fuse with a sub-minimum width fuse line which is programmed with a low trigger voltage snapback.

### BACKGROUND OF THE INVENTION

1. Field of the Invention

The present invention relates generally to E-Fuse and anti-E-Fuse device structures and methods, and more particularly pertains to E-Fuse and anti-E-Fuse device structures and methods which use standard photolithography to pattern and fabricate a final polysilicon wafer imaged structure which is smaller than normal allowable photolithographic minimum dimensions.

2. Discussion of the Prior Art

With the introduction of low-K dielectric back end of lines (BEOL) in semiconductor processes, which are susceptible of being damaged by excessive heat, the low-K materials are moving the design of fuses from being laser blow fuses to electrical blow fuses. Typically, an electrical fuse is subjected to a high electrical current and a silicide melts, producing a significant increase in resistance which is used to sense the fuse blow. One example is a poly resistor wherein sufficient current passes through the resistor to cause sufficient heating to melt a silicide layer thereon. This causes the resistance of the poly resistor to increase from ˜5 ohms/sq up to nearly 200-2000 ohm/sq in the melted silicide area. With silicide on the devices, electrical fuses work well in today's processes. However, in processes where the silicide is not titanium or cobalt, which have a relatively low melting temperature is (<1000C), but instead use a silicide of tungsten or another material which has a very high melting temperature (=>3000C), then new electrical fuse structures are required in these processes. A low-K dielectric is an ideal insulator for electrical fuses, but conventional dielectric materials (e.g. SiO2) provide adequate thermal resistance and insulation to the substrate and concentrate and entrap the heat for polysilicon programming via fuse separation.

### BRIEF SUMMARY OF THE INVENTION

Accordingly, it is a primary object of the present invention to provide E-Fuse and anti-E-Fuse device structures and methods which use standard photolithography to pattern and fabricate a final polysilicon wafer imaged structure which is smaller than normal allowable photolithographic minimum dimensions.

In accordance with the teachings herein, the present invention provides three different methods to fabricate a final polysilicon wafer imaged structure which is smaller than normal allowable photolithographic minimum dimensions. A first method uses a photolithographic mask with a sub-minimum space between minimum size pattern features of the mask, a second method uses a photolithographic mask with a sub-minimum widthwise jog or offset between minimum size pattern features of the mask, and a third method is a combination of the first and second methods. Each of the three methods can be used with three different embodiments, a first embodiment is a polysilicon E-Fuse with a sub-minimum width polysilicon fuse line, a second embodiment is a work function altered/programmed self-aligned MOSFET E-Fuse with a sub-minimum width fuse line, and a third embodiment is a polysilicon MOSFET E-Fuse with a sub-minimum width fuse line which is programmed with a low trigger voltage snapback.

### BRIEF DESCRIPTION OF THE SEVERAL VIEWS OF THE DRAWINGS

The foregoing objects and advantages of the present invention for E-Fuse and anti-E-Fuse device structures and methods may be more readily understood by one skilled in the art with reference being had to the following detailed description of several embodiments thereof, taken in conjunction with the accompanying drawings wherein like elements are designated by identical reference numerals throughout the several views, and in which:

FIG. 1 illustrates a wafer on which an image is being patterned (exposed and etched) by using a mask which defines a sub-minimum space separating two successive longitudinally displaced line features of the mask, each having a minimum line width.

FIG. 2 shows the resultant imaged structure produced by the mask of FIG. 1 which reproduces the two lines of the mask of FIG. 1, and further has a sub-minimum line width in the sub-minimum space.

FIG. 3 illustrates a wafer on which an image is being patterned with a mask which defines a sub-minimum widthwise jog or offset separating two successive line features of the mask.

FIG. 4 illustrates the resultant patterned image produced by the mask of FIG. 3 wherein the patterned image includes a sub-minimum widthwise jog or offset feature joining the two successive line features.

FIG. 5 illustrates a wafer on which an image is being patterned with a mask which defines a sub-minimum space and also defines a sub-minimum widthwise jog or offset separating two successive line features of the mask.

FIG. 6 illustrates the resultant patterned image produced by the mask of FIG. 5 which has a sub-minimum width which is narrower than either of those produced by the methods of FIGS. 1-4.

FIG. 7 illustrates an exemplary first embodiment which is directed to a polysilicon E-Fuse which includes a narrow sub-minimum width polysilicon line to provide increased self heating during programming when a current is passed through the E-Fuse.

FIG. 8 illustrates an exemplary second embodiment which is directed to a work function altered or engineered selfâ [symbol] ″aligned MOSFET E-Fuse which includes a narrow sub-minimum width polysilicon line to provide increased self heating during programming when a current is passed through the MOSFET E-Fuse.

FIG. 9 illustrates an exemplary third embodiment which provides a MOSFET which includes a narrow sub-minimum width polysilicon line to provide increased self heating during programming and wherein an intentional low trigger voltage region is provided by increasing the field in a local region of the channel of the MOSFET.

### DETAILED DESCRIPTION OF THE INVENTION

The present invention uses standard photolithography to pattern and fabricate a final polysilicon wafer imaged structure which is smaller than normal allowable photo-lithographic minimum dimensions. Three different methods are provided to produce such sub-minimum dimension structures.

A first method utilizes standard photolithography to pattern an image using a mask with a sub-minimum space between pattern features of the mask to produce a final image and structure which has a sub-minimum fuse bridge feature.

A second method utilizes standard photolithography to pattern an image using a mask with a sub-minimum widthwise jog or offset between pattern features of the mask to produce a final image and structure which has a sub-minimum jog/offset fuse bridge feature.

A third method is a hybrid or combination of the first and second methods.

Each of these three methods can be used with three different embodiments, thus producing a total of nine different embodiments.

The resultant independent structures are described in the following three embodiments.

A first embodiment is directed to a polysilicon E-Fuse which includes a narrow sub-minimum width polysilicon line to provide increased self heating during programming when a current is passed through the E-Fuse. This embodiment uses a shorted/open/resistance change line to distinguish an unprogrammed/programmed E-Fuse.

A second embodiment is directed to a work function altered or engineered MOSFET selfâ [symbol] “aligned E-Fuse which includes a narrow sub-minimum width polysilicon line to provide increased self heating during programming when a current is passed through the E-Fuse, which drives dopant from the narrow polysilicon line, self-aligning an active area to this region. This embodiment uses the change in the metal-silicon work function caused by the decrease in dopant, which causes a significant decrease in current through the MOSFET E-Fuse, to distinguish an unprogrammed/programmed E-Fuse.

A third embodiment provides a MOSFET which includes a narrow sub-minimum width polysilicon line to provide increased self heating during programming when a current is passed through the E-Fuse, and wherein an intentional low trigger voltage is provided by increasing the field in a local region of the channel of the MOSFET. This causes a low voltage snapback in the MOSFET, which significantly increases the current flow through the MOSFET, such that the device is effectively fused from drain to source, enabling the device to be used as an anti-E-Fuse.

The first method utilizes standard photolithography to pattern an image using a mask with a sub-minimum space between pattern features of the mask to produce a final image and structure which has a sub-minimum fuse bridge feature.

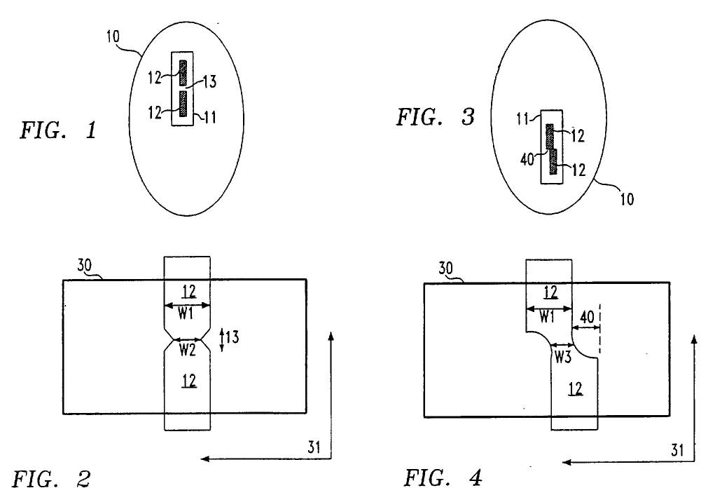

FIG. 1 illustrates a wafer 10 on which an image is being patterned (exposed and etched) by using a mask 11 which defines a sub-minimum space 13 separating two successive longitudinally displaced line features 12 of the mask, each having a minimum normal design line width W1, which will eventually join in the patterned image to produce a continuous feature in the region 13 having a sub-minimum width dimension W2 of ˜0.5 L1.

FIG. 2 shows the resultant imaged structure which reproduces the two lines having a minimum normal design line width W1, and further has a sub-minimum line width W2 in the sub-minimum space 13. In a chip or circuit as shown in FIG. 2, the area/region 30 can be either an active area, which is an area over a thin oxide, or an isolation region, which is a region over a thick oxide, depending on the embodiments described below, while region 31 is always an isolation region over a thick oxide. In a simulation of the structure with W1 ˜0.154 Âμm, and 13=0.05 Âμm, the resultant image had a sub-minimum line width of W2 0.100 Aμm.

The second method utilizes standard photolithography to pattern an image using a mask with a sub-minimum widthwise jog or offset between pattern features of the mask to produce a final image and structure which has a sub-minimum width jog/offset fuse bridge feature. The second method places first and second minimum normal design dimension features adjacent to each other, but displaced width-wise relative to each other by a non-overlapping sub-minimum jog or offset.

FIG. 3 illustrates a wafer 10 on which an image is being patterned (exposed and etched) with a mask 11 which defines a sub-minimum widthwise jog or offset 40, having a dimension of ˜0.5 W1, separating two successive minimum normal design width line features 12 of the mask, each having a minimum width of W1, which will eventually join in the patterned image to produce a continuous feature having a sub-minimum width dimension W2.

FIG. 4 illustrates the resultant patterned image produced by the mask of FIG. 3 wherein the patterned image includes a sub-minimum widthwise jog or offset feature having a width dimension W2 joining the two successive line features 12.

In a chip or circuit as shown in FIG. 4, the area/region 30 can be either an active area or an isolation region, depending on the embodiments described below, while region 31 is always an isolation region. In a simulation of the structure with W1=0.154 um, and 40=0.025−0.01 um, in the resultant image the sub-minimum width W2 ranged from 0.130−0.050 Âμm.

The third method is a combination of the first and second methods, wherein a sub-minimum space 13 in a mask pursuant to the embodiment of FIG. 1 is offset by a sub-minimum widthwise jog/offset 40 in the mask pursuant to the embodiment of FIG. 3.

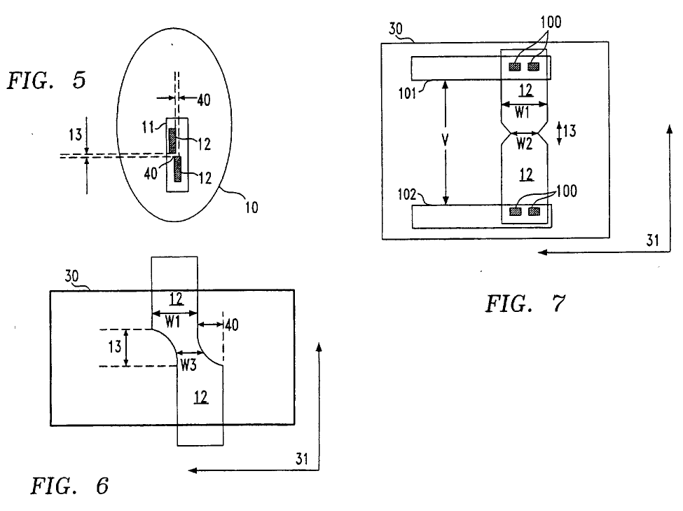

FIG. 5 illustrates a wafer 10 on which an image is being patterned (exposed and etched) with a mask 11 which defines a sub-minimum space 13, having a dimension of ˜0.5 L1, separating two successive longitudinally displaced line features 12 of the mask, each having a minimum normal design width of W1. The mask also defines a sub-minimum widthwise jog or offset 40, having a dimension of ˜0.5 W1, separating the two successive line features 12 of the mask, which will eventually join in the patterned image to produce a continuous feature having a sub-minimum width dimension.

FIG. 6 illustrates a chip or circuit wherein the area/region 30 can be either an active area or an isolation region, depending on the embodiments described below, while region 31 is always an isolation region. The resultant image of FIG. 6 has a sub-minimum width W3 which of is shorter than either of those produced by method 1 or method 2. The space 13 does not necessarily have to be equal to the offset jog 40. A simulation result has indicated that for a jog 40 equal to a space 13 of 0.077 Âμm, and with a minimum line width W1=0.154 Âμm, the resultant image sub-minimum width 13 ranged between 0.075−0.025 Âμm.

In a standard photolithographic process, a photosensitive polymer is deposited on the substrate of the wafer 10, and the photosensitive polymer is exposed to actinic radiation through the mask 11 which has a first minimum normal design size W1 feature and a second normal design minimum size W1 feature that is offset and spaced from the first minimum size feature. The polymer is then developed such that the sub-minimum size W3 feature is defined by the portion of the mask between the first and second minimum size features.

FIG. 7 illustrates an exemplary first embodiment which is directed to a polysilicon E-Fuse which includes a narrow sub-minimum width W2 polysilicon line 12 to provide increased self heating during programming when a current is passed through the E-Fuse. This embodiment uses a shorted/open line to distinguish an unprogrammed/programmed E-Fuse, or alternatively uses a change in resistance to distinguish an unprogrammed/programmed E-Fuse. In the first embodiment, the polysilicon line 12 (which is typically salicided) is used as a normally closed fusible link. Regions 30 and 31 are typically isolation regions. An E-Fuse structure as shown in FIG. 2 is contacted by contacts 100 and interconnect wiring 101, 102. Programming is accomplished by a voltage source V passing a current from 101 to 102, thereby heating the shortened link element 13 and causing the link to open and enter the programmed state. Alternative embodiments can include the sub-minimum E-Fuse structures shown in FIGS. 4 and 6.

Thus, the present invention provides a fuse element formed on a semiconductor substrate of a wafer 10, with the substrate normally having a subset of integrated circuit elements thereon which have a minimum width W1. A conductive line 12 is formed on the substrate and has two end portions connected to 101, 102, and a center portion, all having the minimum width. A link portion 13 is formed within the center portion and spaced from the end portions that has a sub-minimum width W2 less than the width W1. The application of a first power supply voltage to the first end portion 101 and of a second power supply voltage to the second end portion 102 develops a voltage differential V across the end portions and causes an electrical property of the fuse element to undergo a detectable change. The conductive line can include a salicide or silicide thereon which is melted by the application of the fuse voltage V, such that the changed electrical property is the resistance of the conductive line. The spacing between the center portion and the end portions is sufficient to prevent the end portions from serving as a heat sink, which would adversely serve to increase the amount of joule heating required to change the electrical property. In some semiconductor technologies, the minimum width can be approximately 0.13 microns, and the spacing is at least approximately 0.5 microns.

FIG. 8 illustrates an exemplary second embodiment which is directed to a work function altered or engineered selfâ [symbol] “aligned MOSFET E-Fuse which includes a narrow sub-minimum width W2 polysilicon line 12 to provide increased self heating during programming when a current is passed through the MOSFET E-Fuse, which drives the polysilicon dopant (with the salicide) in the direction of the electron wind and from the narrow polysilicon line 12 at W2, 13, self-aligning an active area to this region. This embodiment provides a MOSFET device having a source diffusion S having a contact 104 and interconnect wiring 111 and a drain diffusion D having a contact 106 and interconnect wiring, 112 and a gate under 13.

During programming, the sub-minimum width W2 polysilicon line 12 heats the gate of the MOSFET at W2, 13 to change the metal-silicon work function caused by the decrease in dopant, which causes a significant change in the threshold, thus altering the current flow through the MOSFET E-Fuse, to distinguish an unprogrammed/programmed E-Fuse. In this embodiment, the conductive line comprises a silicided gate of an FET, having an underlying doped poly, and the changed electrical property is the resistance of the FET. Region 30 is a modified active area, and region 31 is an isolation region. FIG. 8 illustrates an E-Fuse structure similar to that shown in FIG. 2 which is contacted by contacts 100 and interconnect wiring 101, 102. Programming is accomplished by passing a current from 101 to 102, thereby heating the shortened link element 13 at W2 and driving the polysilicon dopant (with the salicide) in the direction of the electron wind. This provides a programmed MOSFET whose threshold voltage may be changed as much as 550 mV. Substrate and/or well contacts are not shown in FIG. 8 but are normally present. Alternative embodiments can include the sub-minimum E-Fuse structures shown in FIGS. 4 and 6.

Although previously described preferred embodiments prefer open circuits to distinguish programmed and unprogrammed fuses, the region W2 in FIGS. 2 and 8 can use a reduced power structure to result in a substantial change in the resistance of the line to distinguish programmed and unprogrammed fuses, while not open circuiting the link.

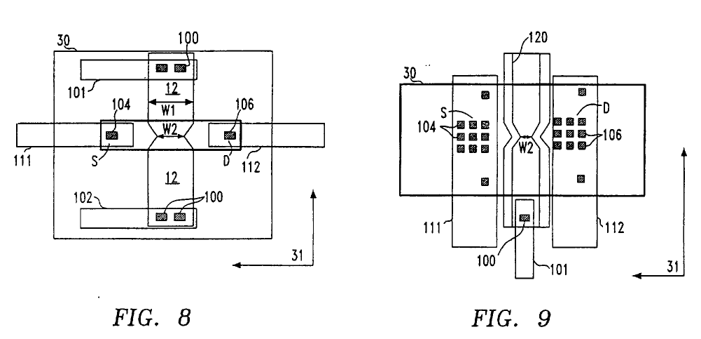

FIG. 9 illustrates an exemplary third embodiment which provides a MOSFET E-Fuse having a source S, source contacts 104, a drain D, drain contacts 106, and a gate between the source S and a drain D under the sub-minimum width W2, and wherein an intentional low trigger voltage region is provided by increasing the field in a local region of the channel of the MOSFET. This causes a low trigger voltage snapback in the MOSFET, which significantly increases the current flow through the device, such that the device is effectively fused or shorted from drain to source, enabling the device to be used as an anti-E-Fuse. By introducing a low voltage snapback, the device is effectively shorted from drain to source, enabling the device for use as an anti-fuse. The MOSFET has only one gate contact 100 and interconnect wire 101. The diffusion contacts 104, 106 are heavily weighted about the shortened channel W2, in order to handle most of the current produced during a snapback program event. Substrate and/or well contacts are not shown in FIG. 9 but are normally present. Alternative embodiments can include the sub-minimum E-Fuse features shown in FIGS. 4 and 6, providing region W2 allows for self-aligning source, drain contacts 104, 106 in the snapback region, which provide a device design for handling high program currents which is an important design feature.

The third embodiment can be fabricated in a process that has non-silicided diffusions, but will also work with silicide, and preferably has tungsten silicide or tungsten nitride clad polysilicon lines. A sufficiently high drain/source voltage (Vds) is applied across the MOSFET device to turn-on the parasitic lateral npn (Lnpn) beneath the NMOS device. Typically for ESD (electrostatic discharge) protection, non-silicided diffusions on the MOSFET device are beneficial because they result in a good current distribution in the width direction. However an electrical anti-fuse should have current crowding in the width direction W2 so that the failure current is as low as possible. The lower the failure current, the smaller the driver needed to supply the fusing current. Having non-silicided diffusions requires a structural change to force the current to crowd in the width direction. Multiple serially arranged implementations of the sub-minimum fuse bridges (multiple serially arranged W2s) are also possible spaced along the length of conductor 12, but the net result is that a small delta W section having a channel width or length shorter than the rest of the device results in the Lnpn direct triggering in this shorter channel width or length area. Current will crowd in this small delta W area, and the device will go into IT2 (short from drain to source) to produce anti-fuse programming.

The embodiment of FIG. 9 can have a contact scheme with unsilicided diffusions to reinforce the effect, but a silicided diffusion is also possible due to the short channel effect imposed by the design of the device. The MOSFET starts in an unprogrammed state (gate grounded initial resistance ˜ Mohms) and changes to a programmed state (gate grounded, resistance ˜ a few ohms) after the drain/short occurs. This results in at minimum a 5 order of magnitude change in resistance. The snapback/trigger voltage is typically needed in normal functioning devices to be=>2 Vdd to allow for enhanced voltage screening. With a sub-minimum Leff (assuming punch-through doesn't occur), this trigger voltage can be reduced even further.

The following table presents sample values for trigger voltage vs. Leff taken from a 0.18 um technology:

| Leff | Trigger/Snapback Voltage (V gate = 0 v) |
|---|---|
| 0.175 um | 5.5 v |
| 0.135 um | 5.0 v |
| 0.100 um | 4.8 v |

While several embodiments and variations of the present invention for E-Fuses and anti E-Fuse device structures are described in detail herein, it should be apparent that the disclosure and teachings of the present invention will suggest many alternative designs to those skilled in the art.

What is claimed is:

1. A fuse element formed on a semiconductor substrate, the substrate having a subset of integrated circuit elements thereon having a minimum normal design width which is smaller than the width of other integrated circuit elements on said substrate and that receive first and second power supply voltages, a conductive line formed on said substrate and having two end portions and a center portion of said minimum normal design width, and a link portion within said center portion and spaced from said end portions which has a sub-minimum width less than said minimum normal design width, wherein an application of said first and second power supply voltages across said end portions causes an electrical property of said fuse element to undergo a detectable change.

2. The fuse element and semiconductor substrate of claim 1, wherein the conductive line includes a silicide thereon.

3. The fuse element and semiconductor substrate of claim 2, wherein the changed electrical property is resistance of the conductive line.

4. The fuse element and semiconductor substrate of claim 1, wherein the conductive line comprises a silicided gate of an FET, having an underlying doped poly.

5. The fuse element and semiconductor substrate of claim 4, wherein the changed electrical property is resistance of the FET.

6. The fuse element and semiconductor substrate of claim 4, wherein the changed electrical property is a threshold voltage of the FET.

7. The fuse element and semiconductor substrate of claim 1, wherein the spacing between the center portion and the end portions is sufficient to prevent the end portions from serving as a heat sink to increase the amount of joule heating required to change the electrical property.

8. The fuse element and semiconductor substrate of claim 7, wherein the minimum normal design width approximately 0.13 microns, and the sub-minimum width is approximately 0.5 microns.

9. The fuse element and semiconductor substrate of claim 7, wherein the link portion is approximately at the center of the center portion.

10. The fuse element and semiconductor substrate of claim 1, including a polysilicon E-Fuse which includes a narrow sub-minimum width polysilicon line to provide increased self heating during programming when a current is passed through the E-Fuse.

11. The fuse element and semiconductor substrate of claim 10, wherein the polysilicon E-fuse uses a shorted/open line to distinguish a programmed/unprogrammed E-Fuse.

12. The fuse element and semiconductor substrate of claim 10, wherein the polysilicon E-fuse uses a change in resistance to distinguish a programmed/unprogrammed E-Fuse.

13. The fuse element and semiconductor substrate of claim 1, including a work function altered MOSFET selfâ [symbol] “aligned E-Fuse which includes a narrow sub-minimum width polysilicon line to provide increased self heating during programming when a current is passed through the E-Fuse, which drives dopant from the narrow polysilicon line, self-aligning an active area to this region, which causes a significant decrease in current through the MOSFET E-Fuse, to distinguish an unprogrammed/programmed E-Fuse.

14. The fuse element and semiconductor substrate of claim 1, including a MOSFET wherein increasing the field in a local region of a channel of the MOSFET causes a low voltage snapback in the MOSFET, which significantly increases the current flow through the MOSFET, such that the device is fused from drain to source, enabling the device to be used as an anti-E-Fuse.

15. The fuse element and semiconductor substrate of claim 1, including a MOSFET wherein increasing the field in a local region of a channel of the MOSFET causes allow voltage snapback in the MOSFET, and which includes a narrow sub-minimum width polysilicon line which allows for self-aligning source and drain contacts in a snapback region which provide a design for handling high program currents.

16. A mask used to form a sub-minimum image, comprising a first minimum size feature, and a second minimum size feature that is offset and spaced from said first minimum size feature.

17. A process of forming a sub-minimum size feature on a substrate, comprising:
forming a photosensitive polymer on the substrate;
exposing said photosensitive polymer to actinic radiation through a mask having a first minimum size feature and a second minimum size feature that is offset and spaced from said first minimum size feature; and
developing said polymer such that said sub-minimum size feature is defined by a portion of the mask between said minimum size features.

18. The process of claim 11, including forming an FET link as the sub-minimum feature.
